(19) United States
(12) Patent Application Publication
(10) Pub. No.: US 2014/0061039 A1
(43) Pub. Date: Mar. 6, 2014

(54) TARGET COOLING FOR PHYSICAL VAPOR DEPOSITION (PVD) PROCESSING SYSTEMS

(71) Applicants: MARTIN LEE RIKER, Milpitas, CA (US); KEITH A. MILLER, Mountain View, CA (US)

(72) Inventors: MARTIN LEE RIKER, Milpitas, CA (US); KEITH A. MILLER, Mountain View, CA (US)

(73) Assignee: APPLIED MATERIALS, INC., Santa Clara, CA (US)

(21) Appl. No.: 13/603,933

(22) Filed: Sep. 5, 2012

(51) Int. Cl. C23C 14/35

(52) U.S. Cl. 204/298.09; 204/298.12

(57) ABSTRACT

Target assemblies for use in a substrate processing system are provided herein. In some embodiments, a target assembly for use in a substrate processing system may include a source material to be deposited on a substrate, a first backing plate configured to support the source material on a front side of the first backing plate, such that a front surface of the source material opposes the substrate when present, a second backing plate coupled to a backside of the first backing plate, and a plurality of sets of channels disposed between the first and second back plates. These channels permit a coolant to be provided closer to the heat source (target face) thereby facilitating more efficient heat removal from the target. More efficient heat removal from the target results in a target with a lesser thermal gradient and therefore less mechanical bowing/deformation.

### FIELD

Embodiments of the present invention generally relate to substrate processing systems, and more specifically, to physical vapor deposition (PVD) processing systems.

### BACKGROUND

In plasma enhanced substrate processing systems, such as physical vapor deposition (PVD) chambers, high power density PVD sputtering with high magnetic fields and high DC Power can produce high energy at a sputtering target, and cause a large rise in surface temperature of the sputtering target. The inventors have observed that backside flooding of target backing plate to cool the target may not be sufficient to capture and remove heat from the target. The inventors have further observed that the remaining heat in the target can result in significant mechanical bowing due to thermal gradient in the sputter material and across backing plate. The mechanical bowing increases as larger size wafers are being processed. This additional size aggravates the tendency of the target to bow/deform under thermal, pressure and gravitational loads. The impacts of bowing may include mechanical stress induced in the target material that can lead to fracture, damage at the target to insulator interface, and changes in distance from a magnet assembly to the face of the target material that can cause changes the plasma properties (e.g., moving the processing regime out of an optimal or desired processing condition which affects the ability to maintain plasma, sputter/deposition rate, and erosion of the target).

Accordingly, the present invention provides improved cooling of target assemblies for use in substrate processing systems.

### SUMMARY

Target assemblies for use in physical vapor deposition (PVD) processing systems are provided herein. In some embodiments, a target assembly for use in a PVD processing system includes a source material to be deposited on a substrate, a first backing plate configured to support the source material on a front side of the first backing plate, such that a front surface of the source material opposes the substrate when present, a second backing plate coupled to a backside of the first backing plate, and a plurality of sets of channels disposed between the first and second back plates.

In at least some embodiments, a substrate processing system is provided that includes a chamber body, a target disposed in the chamber body and comprising a source material to be deposited on a substrate, a first backing plate configured to support the source material, a second backing plate coupled to a backside of the first backing plate, and a plurality of sets of fluid cooling channels disposed between the first and second backing plates, a source distribution plate opposing a backside of the target and electrically coupled to the target, a central support member disposed through the source distribution plate and coupled to the target to support the target assembly within the substrate processing system, a plurality of fluid supply conduits configured to supply heat exchange fluid to the plurality of sets of fluid cooling channels, the plurality of fluid supply conduits having a first end coupled to a plurality of inlets disposed on a backside of the second backing plate, and a second end disposed through a top surface of the chamber body, and a plurality of fluid return conduits configured to return heat exchange fluid from the plurality of sets of fluid cooling channels, the plurality of fluid return conduits having a first end coupled to a plurality of outlets disposed on a backside of the second backing plate, and a second end disposed through a top surface of the chamber body.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic cross sectional view of a process chamber in accordance with some embodiments of the present invention.

FIG. 2 depicts an isometric view of a backing plate of a target assembly in accordance with some embodiments of the present invention.

FIG. 3 depicts a schematic side view of a target assembly in accordance with some embodiments of the present invention.

FIG. 4 depicts a schematic top view of a target assembly in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide improved cooling of target assemblies for use in substrate processing systems through the use of cooling channels running through a backing plate of the target. These channels permit a coolant to be provided closer to the heat source (target face) thereby facilitating more efficient heat removal from the target. More efficiently removing heat from the target results in a target with a lesser thermal gradient and therefore less mechanical bowing/deformation.

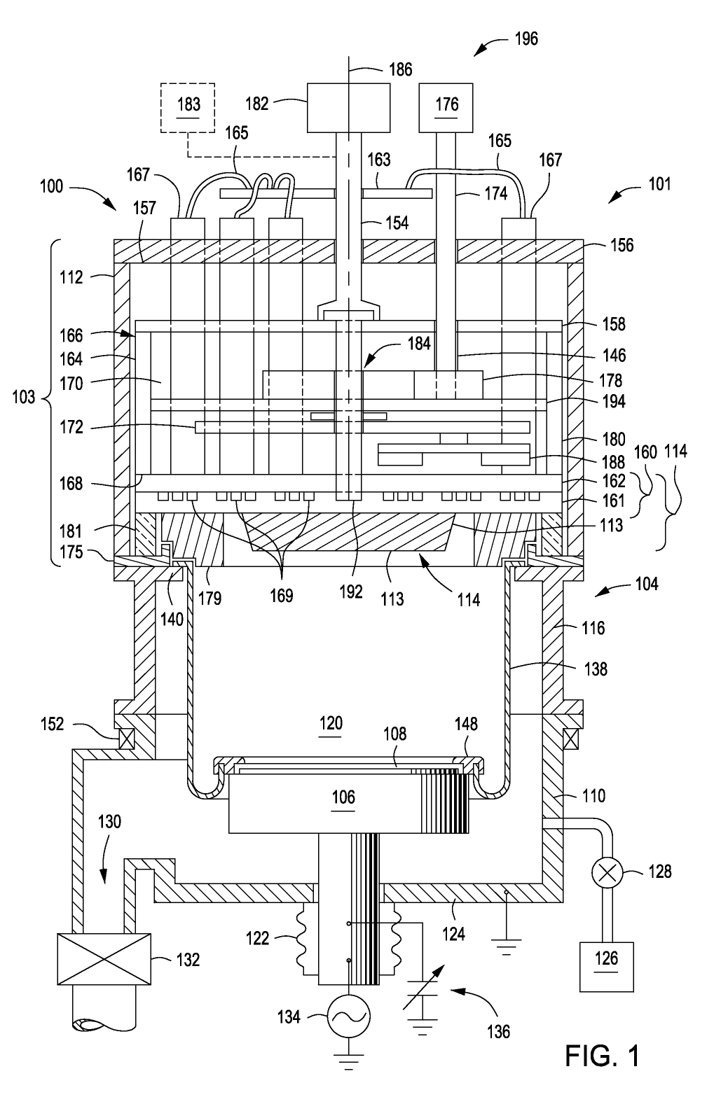

FIG. 1 depicts a simplified, cross-sectional view of a physical vapor deposition (PVD) processing system 100 in accordance with some embodiments of the present invention. Examples of other PVD chambers suitable for modification in accordance with the teachings provided herein include the ALPS® Plus and SIP ENCORE® PVD processing chambers, both commercially available from Applied Materials, Inc., of Santa Clara, Calif. Other processing chambers from Applied Materials, Inc. or other manufactures, including those configured for other types of processing besides PVD, may also benefit from modifications in accordance with the teachings disclosed herein.

In some embodiments of the present invention, the PVD processing system 100 includes a chamber lid 101 removably disposed atop a process chamber 104. The chamber lid 101 may include a target assembly 114 and a grounding assembly 103. The process chamber 104 contains a substrate support 106 for receiving a substrate 108 thereon. The substrate support 106 may be located within a lower grounded enclosure wall 110, which may be a chamber wall of the process chamber 104. The lower grounded enclosure wall 110 may be electrically coupled to the grounding assembly 103 of the chamber lid 101 such that an RF return path is provided to an RF or DC power source 182 disposed above the chamber lid 101. The RF or DC power source 182 may provide RF or DC power to the target assembly 114 as discussed below.

The substrate support 106 has a material-receiving surface facing a principal surface of a target assembly 114 and supports the substrate 108 to be sputter coated in planar position opposite to the principal surface of the target assembly 114. The substrate support 106 may support the substrate 108 in a central region 120 of the process chamber 104. The central region 120 is defined as the region above the substrate support 106 during processing (for example, between the target assembly 114 and the substrate support 106 when in a processing position).

In some embodiments, the substrate support 106 may be vertically movable to allow the substrate 108 to be transferred onto the substrate support 106 through a load lock valve (not shown) in the lower portion of the process chamber 104 and thereafter raised to a deposition, or processing position. A bellows 122 connected to a bottom chamber wall 124 may be provided to maintain a separation of the inner volume of the process chamber 104 from the atmosphere outside of the process chamber 104 while facilitating vertical movement of the substrate support 106. One or more gases may be supplied from a gas source 126 through a mass flow controller 128 into the lower part of the process chamber 104. An exhaust port 130 may be provided and coupled to a pump (not shown) via a valve 132 for exhausting the interior of the process chamber 104 and to facilitate maintaining a desired pressure inside the process chamber 104.

An RF bias power source 134 may be coupled to the substrate support 106 in order to induce a negative DC bias on the substrate 108. In addition, in some embodiments, a negative DC self-bias may form on the substrate 108 during processing. For example, RF energy supplied by the RF bias power source 134 may range in frequency from about 2 MHz to about 60 MHz, for example, non-limiting frequencies such as 2 MHz, 13.56 MHz, or 60 MHz can be used. In other applications, the substrate support 106 may be grounded or left electrically floating. Alternatively or in combination, a capacitance tuner 136 may be coupled to the substrate support 106 for adjusting voltage on the substrate 108 for applications where RF bias power may not be desired.

The process chamber 104 further includes a process kit shield, or shield, 138 to surround the processing volume, or central region, of the process chamber 104 and to protect other chamber components from damage and/or contamination from processing. In some embodiments, the shield 138 may be connected to a ledge 140 of an upper grounded enclosure wall 116 of the process chamber 104. As illustrated in FIG. 1, the chamber lid 101 may rest on the ledge 140 of the upper grounded enclosure wall 116. Similar to the lower grounded enclosure wall 110, the upper grounded enclosure wall 116 may provide a portion of the RF return path between the lower grounded enclosure wall 116 and the grounding assembly 103 of the chamber lid 101. However, other RF return paths are possible, such as via the grounded shield 138.

The shield 138 extends downwardly and may include a generally tubular portion having a generally constant diameter that generally surrounds the central region 120. The shield 138 extends along the walls of the upper grounded enclosure wall 116 and the lower grounded enclosure wall 110 downwardly to below a top surface of the substrate support 106 and returns upwardly until reaching a top surface of the substrate support 106 (e.g., forming a u-shaped portion at the bottom of the shield 138). A cover ring 148 rests on the top of an upwardly extending inner portion of the bottom shield 138 when the substrate support 106 is in its lower, loading position but rests on the outer periphery of the substrate support 106 when it is in its upper, deposition position to protect the substrate support 106 from sputter deposition. An additional deposition ring (not shown) may be used to protect the edges of the substrate support 106 from deposition around the edge of the substrate 108.

In some embodiments, a magnet 152 may be disposed about the process chamber 104 for selectively providing a magnetic field between the substrate support 106 and the target assembly 114. For example, as shown in FIG. 1, the magnet 152 may be disposed about the outside of the chamber wall 110 in a region just above the substrate support 106 when in processing position. In some embodiments, the magnet 152 may be disposed additionally or alternatively in other locations, such as adjacent the upper grounded enclosure wall 116. The magnet 152 may be an electromagnet and may be coupled to a power source (not shown) for controlling the magnitude of the magnetic field generated by the electromagnet.

The chamber lid 101 generally includes the grounding assembly 103 disposed about the target assembly 114. The grounding assembly 103 may include a grounding plate 156 having a first surface 157 that may be generally parallel to and opposite a backside of the target assembly 114. A grounding shield 112 may extending from the first surface 157 of the grounding plate 156 and surround the target assembly 114. The grounding assembly 103 may include a support member 175 to support the target assembly 114 within the grounding assembly 103.

In some embodiments, the support member 175 may be coupled to a lower end of the grounding shield 112 proximate an outer peripheral edge of the support member 175 and extends radially inward to support a seal ring 181, the target assembly 114 and optionally, a dark space shield 179. The seal ring 181 may be a ring or other annular shape having a desired cross-section. The seal ring 181 may include two opposing planar and generally parallel surfaces to facilitate interfacing with the target assembly 114, such as the backing plate assembly 160, on a first side of the seal ring 181 and with the support member 175 on a second side of the seal ring 181. The seal ring 181 may be made of a dielectric material, such as ceramic. The seal ring 181 may insulate the target assembly 114 from the ground assembly 103.

The dark space shield 179 is generally disposed about an outer edge of the target assembly 114, such about an outer edge of a source material 113 of the target assembly 114. In some embodiments, the seal ring 181 is disposed adjacent to an outer edge of the dark space shield 179 (i.e., radially outward of the dark space shield 179). In some embodiments, the dark space shield 179 is made of a dielectric material, such as ceramic. By providing a dielectric dark space shield 179, arcing between the dark space shield and adjacent components that are RF hot may be avoided or minimized. Alternatively, in some embodiments, the dark space shield 179 is made of a conductive material, such as stainless steel, aluminum, or the like. By providing a conductive dark space shield 179 a more uniform electric field may be maintained within the process processing system 100, thereby promoting more uniform processing of substrates therein. In some embodiments, a lower portion of the dark space shield 179 may be made of a conductive material and an upper portion of the dark space shield 179 may be made of a dielectric material.

The support member 175 may be a generally planar member having a central opening to accommodate the dark space shield 179 and the target assembly 114. In some embodiments, the support member 175 may be circular, or disc-like in shape, although the shape may vary depending upon the corresponding shape of the chamber lid and/or the shape of the substrate to be processed in the PVD processing system 100. In use, when the chamber lid 101 is opened or closed, the support member 175 maintains the dark space shield 179 in proper alignment with respect to the target assembly 114, thereby minimizing the risk of misalignment due to chamber assembly or opening and closing the chamber lid 101.

The PVD processing system 100 may include a source distribution plate 158 opposing a backside of the target assembly 114 and electrically coupled to the target assembly 114 along a peripheral edge of the target assembly 114. The target assembly 114 may comprise a source material 113 to be deposited on a substrate, such as the substrate 108 during sputtering, such as a metal, metal oxide, metal alloy, or the like. In embodiments consistent with the present invention, the target assembly 114 includes a backing plate assembly 160 to support the source material 113. The source material 113 may be disposed on a substrate support facing side of the backing plate assembly 160 as illustrated in FIG. 1. The backing plate assembly 160 may comprise a conductive material, such as copper-zinc, copper-chrome, or the same material as the target, such that RF and DC power can be coupled to the source material 113 via the backing plate assembly 160. Alternatively, the backing plate assembly 160 may be non-conductive and may include conductive elements (not shown) such as electrical feedthroughs or the like.

In embodiments consistent with the present invention, the backing plate assembly 160 includes a first backing plate 161 and a second backing plate 162. The first backing plate 161 and the second backing plate 162 may be disc shaped, rectangular, square, or any other shape that may be accommodated by the PVD processing system 100. A front side of the first backing plate is configured to support the source material 113 such that a front surface of the source material opposes the substrate 108 when present. The source material 113 may be coupled to the second backing plate 162 in any suitable manner. For example, in some embodiments, the source material 113 may be diffusion bonded to the first backing plate 161.

A plurality of sets of channels 169 may be disposed between the first and second backing plates 161, 162. In some embodiments consistent with the present invention, the first backing plate 161 may have the plurality of sets of coolant channels 169 formed in a backside of the first backing plate 161 with the second backing plate 162 providing a cap/cover over each of the channels preventing any coolant from leaking. In other embodiments, the plurality of sets of coolant channels 169 may be formed partially in the first backing plate 161 and partially in the second backing plate 162. Still, in other embodiments, the plurality of sets of coolant channels 169 may be formed entirely in the second backing plate 162, while the first backing plate caps/covers each of the plurality of sets of coolant channels 169. The first and second backing plates 161, 162 may be coupled together to form a substantially water tight seal (e.g., a fluid seal between the first and second backing plates) to prevent leakage of coolant provided to the plurality of sets of channels 169. For example, in some embodiments, the first and second backing plates 161, 162 may be brazed together to form a substantially water tight seal. In other embodiments, the first backing plate 161 and the second blacking plate 162 may be coupled by diffusion bonding, brazing, gluing, pinning, riveting, or any other fastening means to provide a liquid seal.

The first and second backing plates 161, 162 may comprise an electrically conductive material, such as an electrically conductive metal or metal alloy including brass, aluminum, copper, aluminum alloys, copper alloys, or the like. In some embodiments, the first backing plate 161 may be a machinable metal or metal alloy (e.g., C182 brass) such that the channels may be machined or otherwise created on a surface of the first backing plate 161. In some embodiments, the second backing plate 162 may be a machinable metal or metal alloy, (e.g., C180 Brass) having a stiffness/elastic modulus greater than the metal or metal alloy of the first backing plate to provide improved stiffness and lower deformation of backing plate assembly 160. The materials and sizes of the first and second backing plates 161, 162 should be such that the stiffness of the entire backing plate assembly 160 will withstand the vacuum, gravitational, thermal, and other forces exerted on the target assembly 114 during deposition process, without (or with very little) deformation or bowing of the target assembly 114 including the source material 113 (i.e., such that the front surface source material 113 remains substantially parallel to the top surface of a substrate 108).

In some embodiments of the present invention, the overall thickness of the target assembly 114 may be between about 20 mm to about 30 mm. For example, the source material 113 may be about 10 to about 15 mm thick and the backing plate assembly may be about 10 to about 15 mm thick. Other thicknesses may also be used.

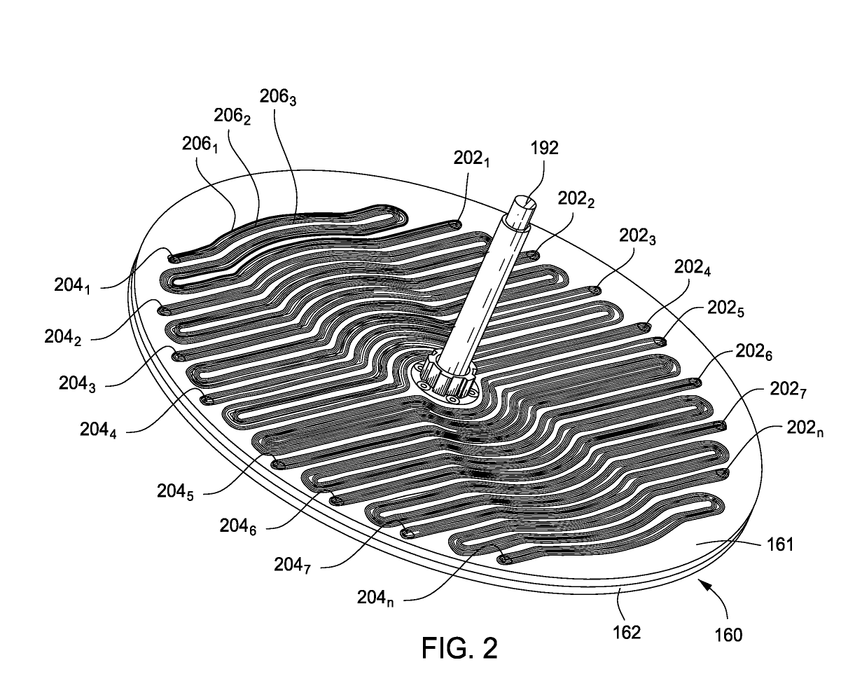

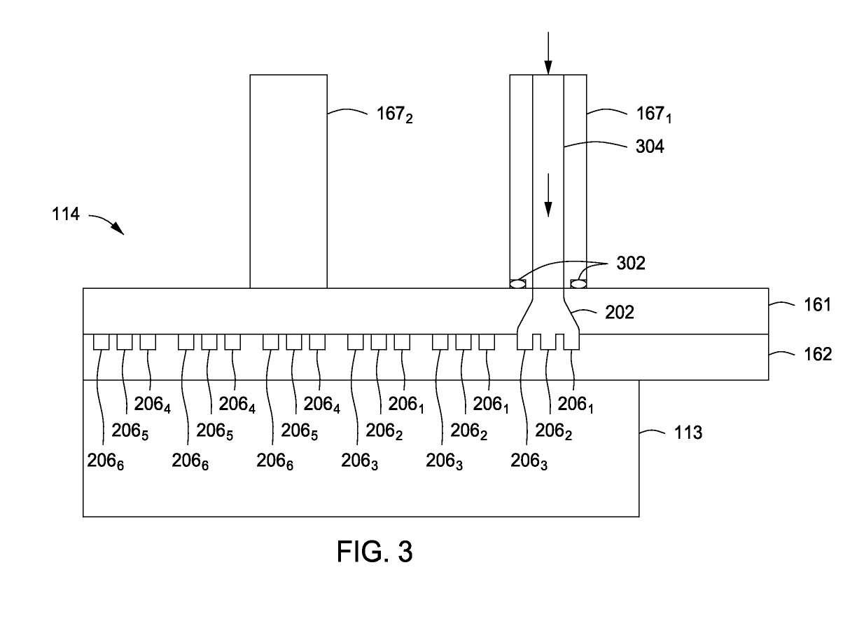

Each set in the plurality of sets of channels 169 may include one or more channels (discussed in detail below with respect to FIGS. 2 and 3). For example, in some exemplary embodiments there may be eight sets of channels, wherein each set of channels includes 3 channels. In other embodiments, there may be more or less sets of channels and more or less channels in each set. The size and cross- sectional shape of each channel, as well as the number of channels in each set and number of sets of channels may be optimized based on one or more of the following characteristics: to provide a desired maximum flow rate through the channel and in total through all channels; to provide maximum heat transfer characteristics; ease and consistency in manufacturing channels within the first and second backing plates 161, 162; to provide the most heat exchange flow coverage over the surfaces of the backing plate assembly 160 while retaining enough structural integrity to prevent deformation of the backing plate assembly 160 under load, etc. In some embodiments, the cross-sectional shape of each conduit may be rectangular, polygonal, elliptical, circular, and the like.

In some embodiments, the second backing plate 162 includes one or more inlets (not shown in FIG. 1 and discussed in detail below with respect to FIGS. 2-4) disposed through the second backing plate 162. The inlets are configured to receive a heat exchange fluid and to provide the heat exchange fluid to the plurality of sets of channels 169. For example, at least one of the one or more inlets may be a plenum to distribute the heat exchange fluid to a plurality of the one or more channels. The second backing plate 162 further includes one or more outlets (not shown in FIG. 1 and discussed in detail below with respect to FIGS. 2-4) disposed through the second backing plate 162 and fluidly coupled to a corresponding inlet by the plurality of sets of channels 169. For example, at least one of the one or more outlets may be a plenum to collect the heat exchange fluid from a plurality of the one or more channels. In some embodiments, one inlet and one outlet are provided and each set of channels in the plurality of set of channels 169 is fluidly coupled to the one inlet and the one outlet.

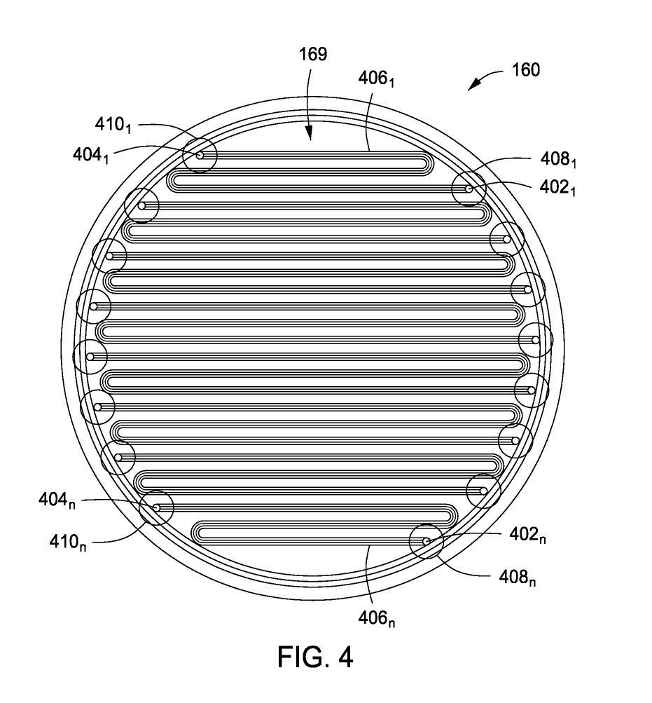

The inlets and outlets may be disposed on or near a peripheral edge of the second backing plate 162. In addition, the inlets and outlets may be disposed on the second backing plate 162 such that supply conduits 167 coupled to the one or more inlets, and return conduits (not shown due to cross section, but shown in FIG. 4) coupled to the one or more outlets, do not interfere with the rotation of a magnetron assembly 196 in cavity 170.

In some embodiments, PVD processing system 100 may include one or more supply conduits 167 to supply heat exchange fluid to the backing plate assembly 160. In some embodiments of the present invention, each inlet on the second backing plate 162 may be coupled to a corresponding supply conduit 167. Similarly, each outlet on the second backing plate 162 may be coupled to a corresponding return conduit (shown in FIG. 4). Supply conduits 167 and return conduits may be made of insulating materials. The fluid supply conduit 167 may include a seal ring (e.g., a compressible o-ring or similar gasketing material) to prevent heat exchange fluid leakage between the fluid supply conduit 167 and an inlet on the backside of the second backing plate 162. In some embodiments, a top end of supply conduits 167 may be coupled to a fluid distribution manifold 163 disposed on the top surface of the chamber body 101. The fluid distribution manifold 163 may be fluidly coupled to the plurality of fluid supply conduits 167 to supply heat exchange fluid to each of the plurality of fluid supply conduits via supply lines 165. Similarly, a top end of return conduits may be coupled to a return fluid manifold (not shown, but similar to 163) disposed on the top surface of the chamber body 101. The return fluid manifold may be fluidly coupled to the plurality of fluid return conduits to return heat exchange fluid from each of the plurality of fluid return conduits via return lines.

The fluid distribution manifold 163 may be coupled to a heat exchange fluid source (not shown) to provide a heat exchange fluid to the backing plate assembly 160. The heat exchange fluid may be any process compatible coolant, such as ethylene glycol, deionized water, a perfluorinated polyether (such as Galden®, available from Solvay S. A.), or the like, or solutions or combinations thereof. In some embodiments, the flow of coolant through the channels 169 may be about 8 to about 20 gallons per minute, in sum total, although the exact flows will depend upon the configuration of the coolant channels, available coolant pressure, or the like.

A conductive support ring 164, having a central opening, is coupled to a backside of the second backing plate 162 along a peripheral edge of the second backing plate 162. In some embodiments, in place of separate supply and return conduits, the conductive support ring 164 may include a ring inlet to receive heat exchange fluid from a fluid supply line (not shown). The conductive support ring 164 may include an inlet manifold, disposed within the body of the conductive support ring 164, to distribute the heat exchange fluid to the plurality of inlets disposed through the second backing plate. The conductive support ring 164 may include an outlet manifold, disposed within the body of the conductive support ring 164, to receive the heat exchange fluid from the plurality of outlets, and a ring outlet to output the heat exchange fluid from the conductive support ring 164. The conductive support ring 164 and the backing plate assembly 160 may be threaded together, pinned, bolted, or fastened in a process compatible manner to provide a liquid seal between the conductive support ring 164 and the second backing plate 161. O-rings or other suitable gasketing materials may be provided to facilitate providing a seal between the conductive support ring 164 and he second backing plate 161.

In some embodiments, the target assembly 114 may further comprise a central support member 192 to support the target assembly 114 within the chamber body 101. The central support member 192 may be coupled to a center portion of the first and second backing plates 161, 162 and extend perpendicularly away from the backside of the second backing plate 162. In some embodiments, a bottom portion of the central support member 192 may be threaded into a central opening in the first and second backing plates 161, 162. In other embodiments, a bottom portion of the central support member 192 may be bolted or clamped to a central portion of the first and second backing plates 161, 162. A top portion of the central support member 192 may be disposed through source distribution plate 158 and includes a feature which rests on a top surface of the source distribution plate 158 that supports the central support member 192 and target assembly 114.

In some embodiments, the conductive support ring 164 may be disposed between the source distribution plate 158 and the backside of the target assembly 114 to propagate RF energy from the source distribution plate to the peripheral edge of the target assembly 114. The conductive support ring 164 may be cylindrical, with a first end 166 coupled to a target-facing surface of the source distribution plate 158 proximate the peripheral edge of the source distribution plate 158 and a second end 168 coupled to a source distribution plate-facing surface of the target assembly 114 proximate the peripheral edge of the target assembly 114. In some embodiments, the second end 168 is coupled to a source distribution plate facing surface of the backing plate assembly 160 proximate the peripheral edge of the backing plate assembly 160.

The PVD processing system 100 may include a cavity 170 disposed between the backside of the target assembly 114 and the source distribution plate 158. The cavity 170 may at least partially house a magnetron assembly 196 as discussed below. The cavity 170 is at least partially defined by the inner surface of the conductive support ring 164, a target facing surface of the source distribution plate 158, and a source distribution plate facing surface (e.g., backside) of the target assembly 114 (or backing plate assembly 160).

An insulative gap 180 is provided between the grounding plate 156 and the outer surfaces of the source distribution plate 158, the conductive support ring 164, and the target assembly 114 (and/or backing plate assembly 160). The insulative gap 180 may be filled with air or some other suitable dielectric material, such as a ceramic, a plastic, or the like. The distance between the grounding plate 156 and the source distribution plate 158 depends on the dielectric material between the grounding plate 156 and the source distribution plate 158. Where the dielectric material is predominantly air, the distance between the grounding plate 156 and the source distribution plate 158 may be between about 15 mm and about 40 mm.

The grounding assembly 103 and the target assembly 114 may be electrically separated by the seal ring 181 and by one or more of insulators (not shown) disposed between the first surface 157 of the grounding plate 156 and the backside of the target assembly 114, e.g., a non-target facing side of the source distribution plate 158.

The PVD processing system 100 has an RF power source 182 connected to an electrode 154 (e.g., a RF feed structure). The electrode 154 may pass through the grounding plate 156 and is coupled to the source distribution plate 158. The RF power source 182 may include an RF generator and a matching circuit, for example, to minimize reflected RF energy reflected back to the RF generator during operation. For example, RF energy supplied by the RF power source 182 may range in frequency from about 13.56 MHz to about 162 MHz or above. For example, non-limiting frequencies such as 13.56 MHz, 27.12 MHz, 40.68 MHz, 60 MHz, or 162 MHz can be used.

In some embodiments, PVD processing system 100 may include a second energy source 183 to provide additional energy to the target assembly 114 during processing. In some embodiments, the second energy source 183 may be a DC power source to provide DC energy, for example, to enhance a sputtering rate of the target material (and hence, a deposition rate on the substrate). In some embodiments, the second energy source 183 may be a second RF power source, similar to the RF power source 182, to provide RF energy, for example, at a second frequency different than a first frequency of RF energy provided by the RF power source 182. In embodiments where the second energy source 183 is a DC power source, the second energy source may be coupled target assembly 114 in any location suitable to electrically couple the DC energy to the target assembly 114, such as the electrode 154 or some other conductive member (such as the source distribution plate 158, discussed below). In embodiments where the second energy source 183 is a second RF power source, the second energy source may be coupled to the target assembly 114 via the electrode 154.

The electrode 154 may be cylindrical or otherwise rod-like and may be aligned with a central axis 186 of the PVD chamber 100 (e.g., the electrode 154 may be coupled to the target assembly at a point coincident with a central axis of the target, which is coincident with the central axis 186). The electrode 154, aligned with the central axis 186 of the PVD chamber 100, facilitates applying RF energy from the RF source 182 to the target assembly 114 in an axisymmetrical manner (e.g., the electrode 154 may couple RF energy to the target at a “single point” aligned with the central axis of the PVD chamber). The central position of the electrode 154 helps to eliminate or reduce deposition asymmetry in substrate deposition processes. The electrode 154 may have any suitable diameter. For example, although other diameters may be used, in some embodiments, the diameter of the electrode 154 may be about 0.5 to about 2 inches. The electrode 154 may generally have any suitable length depending upon the configuration of the PVD chamber. In some embodiments, the electrode may have a length of between about 0.5 to about 12 inches. The electrode 154 may be fabricated from any suitable conductive material, such as aluminum, copper, silver, or the like. Alternatively, in some embodiments, the electrode 154 may be tubular. In some embodiments, the diameter of the tubular electrode 154 may be suitable, for example, to facilitate providing a central shaft for the magnetron.

The electrode 154 may pass through the ground plate 156 and is coupled to the source distribution plate 158. The ground plate 156 may comprise any suitable conductive material, such as aluminum, copper, or the like. The open spaces between the one or more insulators (not shown) allow for RF wave propagation along the surface of the source distribution plate 158. In some embodiments, the one or more insulators may be symmetrically positioned with respect to the central axis 186 of the PVD processing system. Such positioning may facilitate symmetric RF wave propagation along the surface of the source distribution plate 158 and, ultimately, to a target assembly 114 coupled to the source distribution plate 158. The RF energy may be provided in a more symmetric and uniform manner as compared to conventional PVD chambers due, at least in part, to the central position of the electrode 154.

One or more portions of a magnetron assembly 196 may be disposed at least partially within the cavity 170. The magnetron assembly provides a rotating magnetic field proximate the target to assist in plasma processing within the process chamber 101. In some embodiments, the magnetron assembly 196 may include a motor 176, a motor shaft 174, a gearbox 178, a gearbox shaft assembly 184, and a rotatable magnet (e.g., a plurality of magnets 188 coupled to a magnet support member 172), and divider 194.

In some embodiments, the magnetron assembly 196 is rotated within the cavity 170. For example, in some embodiments, the motor 176, motor shaft 174, gear box 178, and gearbox shaft assembly 184 may be provided to rotate the magnet support member 172. In conventional PVD chambers having magnetrons, the magnetron drive shaft is typically disposed along the central axis of the chamber, preventing the coupling of RF energy in a position aligned with the central axis of the chamber. To the contrary, in embodiments of the present invention, the electrode 154 is aligned with the central axis 186 of the PVD chamber. As such, in some embodiments, the motor shaft 174 of the magnetron may be disposed through an off-center opening in the ground plate 156. The end of the motor shaft 174 protruding from the ground plate 156 is coupled to a motor 176. The motor shaft 174 is further disposed through a corresponding off-center opening through the source distribution plate 158 (e.g., a first opening 146) and coupled to a gear box 178. In some embodiments, one or more second openings (not shown) may be disposed though the source distribution plate 158 in a symmetrical relationship to the first opening 146 to advantageously maintain axisymmetric RF distribution along the source distribution plate 158. The one or more second openings may also be used to allow access to the cavity 170 for items such as optical sensors or the like.

The gear box 178 may be supported by any suitable means, such as by being coupled to a bottom surface of the source distribution plate 158. The gear box 178 may be insulated from the source distribution plate 158 by fabricating at least the upper surface of the gear box 178 from a dielectric material, or by interposing an insulator layer (not shown) between the gear box 178 and the source distribution plate 158, or the like, or by constructing the motor drive shaft 174 out of a suitable dielectric material. The gear box 178 is further coupled to the magnet support member 172 via the gear box shaft assembly 184 to transfer the rotational motion provided by the motor 176 to the magnet support member 172 (and hence, the plurality of magnets 188).

The magnet support member 172 may be constructed from any material suitable to provide adequate mechanical strength to rigidly support the plurality of magnets 188. For example, in some embodiments, the magnet support member 188 may be constructed from a non-magnetic metal, such as non-magnetic stainless steel. The magnet support member 172 may have any shape suitable to allow the plurality of magnets 188 to be coupled thereto in a desired position. For example, in some embodiments, the magnet support member 172 may comprise a plate, a disk, a cross member, or the like. The plurality of magnets 188 may be configured in any manner to provide a magnetic field having a desired shape and strength.

Alternatively, the magnet support member 172 may be rotated by any other means with sufficient torque to overcome the drag caused on the magnet support member 172 and attached plurality of magnets 188, when present, in the cavity 170. For example, in some embodiments, (not shown), the magnetron assembly 196 may be rotated within the cavity 170 using a motor 176 and motor shaft 174 disposed within the cavity 170 and directly connected to the magnet support member 172 (for example, a pancake motor). The motor 176 must be sized sufficiently to fit within the cavity 170, or within the upper portion of the cavity 170 when the divider 194 is present. The motor 176 may be an electric motor, a pneumatic or hydraulic drive, or any other process-compatible mechanism that can provide the required torque.

FIG. 2 is an isometric view of a backing plate 160 of target assembly 114 in accordance with some embodiments of the present invention. The first backing plate 161 and the second blacking plate 162 as described above with respect to FIG. 1. A plurality of inlets 202₁₋ₙ are disposed on a peripheral edge of, and completely through, the second blacking plate 162 to provide heat exchange fluid flow to the plurality of sets of channels 169. In addition, a plurality of outlets 204₁₋ₙ are disposed on a peripheral edge of, and completely through, the second blacking plate 162 to provide heat exchange fluid flow from the plurality of sets of channels 169. Each fluid inlet 202₁₋ₙ is fluidly coupled to a corresponding fluid outlet 204₁₋ₙ via a set of channels 206 from the plurality of sets of channels 169. For example, as shown in FIG. 2, in some embodiments, fluid inlet 202₁ is coupled to a set of three fluid channels 206₁₋₃. In some embodiments, the set of three fluid channels 206₁₋₃ traverses the width of the backing plate assembly (between the first and second blacking plates 161, 162) in a recursive manner (for example extending toward the outlet, returning toward the inlet, and extending again toward the outlet) and terminates at fluid outlet 204₁. By flowing heat exchange fluid through the sets of channels in a recursive pattern, a more uniform temperature gradient across the backing plate, and therefore across the source material (113 in FIG. 1), can be maintained. Specifically, cold heat exchange fluid enters inlet 202₁ for example, and heats up as it flows through the set of three fluid channels 206₁₋₃ towards the outlet end of the backing plate assembly 160. The set of three fluid channels 206₁₋₃ then circles back towards the inlet end of the backing plate assembly 160 with the heat exchange fluid at a higher temperature. By recursively flowing the heat exchange fluid, the average temperature of the inlet side and the outlet side of the backing plate assembly 160, and therefore across the source material (113 in FIG. 1), is more uniform.

Although shown in a specific recursive pattern, other patterns having different numbers of passes and/or different geometries may also be used. For example, FIG. 4 depicts a schematic top view of a backing plate assembly 160 in accordance with some embodiments of the present invention where the plurality of sets of channels 169 each include one channel 406-₁₋ₙ. Each channel 406₁₋ₙ is fluidly coupled to an inlet 402₁₋ₙ and an outlet 404₁₋ₙ. Each inlet 402₁₋ₙ is fluidly coupled to a to a supply conduit 408₁₋ₙ. Each outlet 404₁₋ₙ is fluidly coupled to a return conduit 410₁₋ₙ. Still other variations are contemplated.

Returning to FIG. 2, in some embodiments of the present invention, when the central support member 192 is disposed in a center of the backing plate assembly 160, the plurality of set of channels 169 are configured such that they flow around central support member 192. Although the backing plate assembly 160 in FIG. 2 is shown with eight inlets 202₁₋ₙ, eight outlets 204₁₋ₙ, and eights sets of channels 206, other combinations of inlets, outlets, and numbers of channels may be used to provide a desired (e.g., uniform) temperature gradient across the backing plate.

FIG. 3 is a schematic cross sectional view of supply conduit 167ₙ coupled to target assembly 114 in accordance with some embodiments of the present invention. The supply conduit 167₁ includes a central opening 304 and may be coupled to a backside of the second backing plate 162 to supply heat exchange fluid through the backing plate assembly 160. In some embodiments, the supply conduit 167₁ may have an seal ring 302 (e.g., a compressible o-ring or the like) disposed along the bottom of the supply conduit 167₁, which, when coupled to the backside of the second backing plate 162, forms a seal to prevent heat exchange fluid from leaking out. In some embodiments, the supply conduit 167₁ is fluidly coupled to an inlet 202 disposed through the second backing plate 162. In some embodiments, the inlet 202 is fluidly coupled to a set of channels 206₁₋₃ disposed in the first backing plate 161 which is coupled to the second backing plate 162. The heat exchange fluid flows through backing plate assembly 160 via channels 206₁₋₃ to cool the source material 113 coupled to the first backing plate 161. Similarly, the heat exchange fluid is provided by supply conduit 167₂ and flows through backing plate assembly 160 via channels 206₄₋₆ to cool the source material 113 coupled to the first backing plate 161. Corresponding return conduits (not shown) are fluidly coupled to each set of channels 206 (via outlets disposed through first backing plate 161) to remove heated fluid from backing plate assembly 160.

While the foregoing is directed to embodiments of the present invention, other and further embodiments of the invention may be devised without departing from the basic scope thereof.

1. A target assembly for use in a physical vapor deposition substrate processing chamber, comprising:
a source material;
a first backing plate configured to support the source material on a front side of the first backing plate;
a second backing plate coupled to a backside of the first backing plate; and
a plurality of sets of channels disposed between the first and second back plates.

2. The target assembly of claim 1, wherein the second backing plate comprises:
at least one inlet disposed through the second backing plate and configured to receive a heat exchange fluid and to provide the heat exchange fluid to the plurality of sets of channels; and
at least one outlet disposed through the second backing plate and fluidly coupled to the at least one inlet by the plurality of sets of channels.

3. The target assembly of claim 1, wherein the second backing plate comprises:
a plurality of inlets disposed through the second backing plate and configured to receive a heat exchange fluid and to provide the heat exchange fluid to the plurality of sets of channels; and
a plurality of outlets disposed through the second backing plate, wherein each set of channels of the plurality of sets of channels is coupled to a corresponding one of the plurality of inlets and a corresponding one of the plurality of outlets, such that each of the plurality of outlets is fluidly coupled to one of the plurality of inlets by one set of channels of the plurality of sets of channels.

4. The target assembly of claim 1, wherein each set of channels of the plurality of sets of channels traverses a length of the first and second backing plates in a recursive pattern.

5. The target assembly of claim 1, wherein each channel in the plurality of sets of channels is formed completely in the first backing plate, and wherein the second backing plate is configured to cover each channel.

6. The target assembly of claim 1, wherein each channel in the plurality of sets of channels is formed by a groove in the first backing plate and a corresponding groove in the second backing plate.

7. The target assembly of claim 1, wherein the first and second backing plates are brazed together to form a fluid seal between the first and second backing plates.

8. The target assembly of claim 1, wherein the first backing plate comprises an electrically conductive machinable metal or metal alloy, and wherein each channel is a machined groove in the first backing plate.

9. The target assembly of claim 1, wherein the second backing plate comprises an electrically conductive metal or metal alloy having an elastic modulus greater than the metal or metal alloy of the first backing plate.

10. The target assembly of claim 1, wherein each channel in the plurality of sets of channels has a substantially rectangular cross section.

11. The target assembly of claim 1, wherein the first and second backing plates are disc shaped.

12. The target assembly of claim 1, wherein each set of channels comprises one or more channels.

13. The target assembly of claim 1, wherein each set of channels comprises a plurality of channels.

14. The target assembly of claim 2, further comprising:
at least one fluid supply conduit coupled to the at least one inlet on a backside of the second backing plate, wherein each of the at least one fluid supply conduit includes a seal ring to prevent heat exchange fluid leakage; and
at least one fluid return conduit coupled to the at least one outlet on the backside of the second backing plate, wherein each of the at least one fluid return conduit includes a seal ring to prevent heat exchange fluid leakage.

15. The target assembly of claim 3, further comprising:
a plurality of fluid supply conduits, each of the plurality of fluid supply conduits coupled to a corresponding one of the plurality of inlets on a backside of the second backing plate, wherein each of the plurality of fluid supply conduits includes a seal ring to prevent heat exchange fluid leakage; and
a plurality of fluid return conduits, each of the plurality of fluid return conduits coupled to a corresponding one of the plurality of outlets on a backside of the second backing plate, wherein each of the plurality of fluid return conduits includes a seal ring to prevent heat exchange fluid leakage.

16. The target assembly of claim 1, further comprising a central support member to support the target assembly within the substrate processing system, wherein the central support member is coupled to a center portion of the first and second backing plates and extends perpendicularly away from the backside of the second backing plate.

17. The target assembly of claim 3, further comprising a support ring, having a central opening and coupled to a backside of the second backing plate along a peripheral edge of the second backing plate, wherein the support ring comprises a ring inlet to receive heat exchange fluid, an inlet manifold to distribute the heat exchange fluid to the plurality of inlets disposed through the second backing plate, an outlet manifold to receive the heat exchange fluid from the plurality of outlets, and a ring outlet to output the heat exchange fluid from the support ring.

18. A physical vapor deposition substrate processing chamber, comprising:
a chamber body;
a target disposed in the chamber body and comprising a source material to be deposited on a substrate, a first backing plate configured to support the source material, a second backing plate coupled to a backside of the first backing plate, and a plurality of sets of fluid cooling channels disposed between the first and second backing plates;
a source distribution plate opposing a backside of the target and electrically coupled to the target;
a central support member disposed through the source distribution plate and coupled to the target to support the target assembly within the substrate processing system;
a plurality of fluid supply conduits configured to supply heat exchange fluid to the plurality of sets of fluid cooling channels, the plurality of fluid supply conduits having a first end coupled to a plurality of inlets disposed on a backside of the second backing plate, and a second end disposed through a top surface of the chamber body; and
a plurality of fluid return conduits configured to return heat exchange fluid from the plurality of sets of fluid cooling channels, the plurality of fluid return conduits having a first end coupled to a plurality of outlets disposed on a backside of the second backing plate, and a second end disposed through a top surface of the chamber body.

19. The physical vapor deposition substrate processing chamber of claim 18, further comprising:
a cavity disposed between the backside of the target and the source distribution plate; and
a magnetron assembly comprising (a) a rotatable magnet disposed within the cavity and having an axis of rotation that is aligned with a central axis of the target and a central axis the central support member, and (b) a shaft disposed through an opening in the source distribution plate that is not aligned with the central axis of the target and rotationally coupled to the rotatable magnet.

20. The physical vapor deposition substrate processing chamber of claim 18, further comprising:
a fluid distribution manifold disposed on the top surface of the chamber body, fluidly coupled to the plurality of fluid supply conduits to supply heat exchange fluid to each of the plurality of fluid supply conduits; and
a fluid return manifold disposed on the top surface of the chamber body, fluidly coupled to the plurality of fluid return conduits to receive heat exchange fluid from each of the plurality of fluid return conduits.
